(19) United States
(12) Patent Application Publication
(10) Pub. No.: US 2022/0051693 A1
(43) Pub. Date: Feb. 17, 2022

(54) MAGNETIC RECORDING MEDIUM, METHOD OF MANUFACTURING THE SAME, AND MAGNETIC RECORDING/REPRODUCING APPARATUS

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Hiroyuki HYODO, Yokohama Kanagawa (JP)

(21) Appl. No.: 17/191,311

(22) Filed: Mar. 3, 2021

(30) Foreign Application Priority Data
Aug. 11, 2020 (JP) 2020-135879

(51) Int. Cl. G11B 5/706; G11B 5/73; C23C 16/26

(52) U.S. Cl. CPC G11B 5/70615; G11B 2005/0021; C23C 16/26; G11B 5/7366

(57) ABSTRACT

According to one embodiment, a magnetic recording medium includes a substrate, a magnetic recording layer on the substrate, and a first protective layer of carbon formed on the magnetic recording layer by thermal CVD.

### CROSS-REFERENCE TO RELATED APPLICATIONS

This application is based upon and claims the benefit of priority from Japanese Patent Application No. 2020-135879, filed Aug. 11, 2020, the entire contents of which are incorporated herein by reference.

### FIELD

Embodiments described herein relate generally to a magnetic recording medium, a method of manufacturing the same, and a magnetic recording/reproducing apparatus.

### BACKGROUND

Heat-assisted magnetic recording is a recording system in which optical recording and magnetic recording are merged with each other. Using a medium with high coercive force on which no information can be recorded by normal magnetic recording, a magnetic field is applied to the medium while heating the medium with laser light to record information on the medium and reproduce the information at room temperature.

For a magnetic layer of the medium, for example, a magnetic material having an L1₀ crystal structure with a high magnetic anisotropy can be used. The magnetic material needs to be heated at a high temperature to form a film. If, however, the magnetic material is heated at a high temperature, the crystal grains tend to aggregate and the surface smoothness tends to deteriorate, which is likely to adversely influence the reliability of the recording system.

A carbon protective layer is formed on the magnetic layer by sputtering, plasma CVD, filtered cathodic arc, or the like. In order to obtain a high-density carbon film by these film forming methods, a film forming temperature of 200° C. or lower is desirable. In the heat-assisted recording medium, the magnetic layer is heated at a temperature of 500° C. or higher. If, therefore, carbon films are formed continuously after the magnetic layer is formed, the temperature is difficult to decrease sufficiently, which deteriorates the film quality.

### BRIEF DESCRIPTION OF THE DRAWINGS

FIG. 1 is a sectional view showing an exemplary configuration of a magnetic recording medium according to a first embodiment.

FIG. 2 is a flowchart showing a method of manufacturing a magnetic recording medium according to a second embodiment.

FIG. 3 is a sectional view showing another exemplary configuration of the magnetic recording medium according to the first embodiment.

FIG. 4 is a block diagram illustrating a configuration of a hard disk drive (HDD) according to the first embodiment.

FIG. 5 is a side view showing a magnetic head and a suspension in the HDD of FIG. 4.

FIG. 6 is a sectional view showing a magnetic head.

FIG. 7 is an enlarged sectional view showing a head portion of the magnetic head.

FIG. 8 is a sectional view showing a configuration of a magnetic recording medium according to example 1.

FIG. 9 is a flowchart showing a method of manufacturing a magnetic recording medium according to example 2.

FIG. 10 is a sectional view showing a configuration of a magnetic recording medium according to example 2.

### DETAILED DESCRIPTION

In general, according to one embodiment, a magnetic recording medium comprises, a substrate, a magnetic recording layer on the substrate, and a first protective layer of carbon formed on the magnetic recording layer by thermal CVD.

Embodiments will be described below with reference to the drawings.

The disclosure is merely an example and is not limited by contents described in the embodiments described below. Modification which is easily conceivable by a person of ordinary skill in the art comes within the scope of the disclosure as a matter of course. In order to make the description clearer, the sizes, shapes and the like of the respective parts may be changed and illustrated schematically in the drawings as compared with those in an accurate representation. Constituent elements corresponding to each other in a plurality of drawings are denoted by the same reference numerals and their detailed descriptions may be omitted unless necessary.

FIG. 1 is a sectional view showing an exemplary configuration of a magnetic recording medium according to a first embodiment.

As shown in FIG. 1, a magnetic recording medium 300 is so configured that a magnetic recording layer 302 and a first protective layer 303, which is formed of carbon by thermal CVD, are stacked above a substrate 301. Between the substrate 301 and the magnetic recording layer 302, a heat sink layer 307 for suppressing the expansion of a heating region and a crystal orientation layer 308 for improving the orientation of the magnetic recording layer can be provided. In addition, a liquid lubricant layer 305′ can be provided on the first protective layer 303.

In the magnetic recording medium according to the first embodiment, the first protective layer formed of carbon is limited to one formed using thermal CVD.

The CVD is a method in which source gases are decomposed by energy such as heat and plasma and deposited on the substrate surface. Employing a surface reaction, steps such as unevenness and grooves are filled to obtain a film having good surface coating. Table 1 below shows comparisons of film forming temperature and surface coating between thermal CVD and plasma CVD.

TABLE 1

| Film forming | Film forming | Surface |
|---|---|---|
| method | temperature | coating |
| Thermal CVD | High | Better |
| Plasma CVD | Low | Good |

As shown in Table 1, in plasma CVD, the surface coating is good at a relatively low temperature of about 200° C. If, however, a film is formed at a higher temperature, its surface coating lowers, its smoothness deteriorates, and its quality reduces. On the other hand, in thermal CVD, a film having better surface coating can be formed at a relatively high temperature of 300° C. to 500° C. in accordance with source gases. Thus, when a carbon film is formed at temperature exceeding 200° C., there is a difference in surface coating between plasma CVD and thermal CVD.

According to the first embodiment, even though a first protective layer is formed of carbon by thermal CVD at a high temperature after a magnetic recording layer is formed, its surface coating is good and thus its surface smoothness is also good.

The magnetic recording medium according to the first embodiment is more advantageous than a magnetic recording layer formed at a high temperature. For example, a magnetic recording layer of a CoPt type is formed at temperature between room temperature and 300° C., whereas a magnetic recording layer having an L1₀ crystal structure used for a magnetic recording layer for heat-assisted recording is formed by being heated at a temperature of 500° C. or higher in order to improve magnetic characteristics, with the result that crystal grains aggregate and the surface of the layer easily becomes rough. In addition, when a first protective layer is formed continuously after the magnetic recording layer, it is maintained at a high temperature close to 500° C. because the substrate or the magnetic recording layer cannot be cooled immediately under vacuum. In contrast, according to the first embodiment, the use of thermal CVD improves the surface coating of the first protective layer even though it is formed at a high temperature of 500° C., with the result that steps of the magnetic recording layer can be filled and thus the surface smoothness becomes good.

A second embodiment is directed to a method of manufacturing the magnetic recording medium according to the first embodiment. The method includes a step of forming a heat sink layer on a substrate, a step of forming a crystal orientation layer, a step of forming a magnetic recording layer and a step of forming a first protective layer of carbon on the magnetic recording layer by thermal CVD.

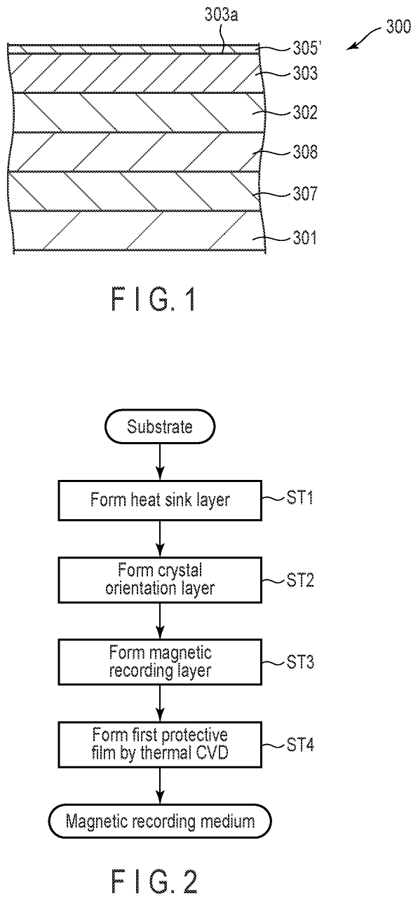

FIG. 2 is a flowchart showing one example of the method of manufacturing a magnetic recording medium according to the second embodiment.

As shown in the flowchart of FIG. 2, first, a substrate is prepared and heated to form a heat sink layer on the substrate (ST1). Then, a crystal orientation layer is formed on the heat sink layer (ST2). After that, a magnetic recording medium is prepared (ST3). Then, a first protective layer is formed of carbon thermal CVD (ST4). The magnetic recording medium can thus be obtained. Furthermore, a liquid lubricant layer can be formed by applying a liquid lubricant onto the first protective layer to form a liquid lubricant layer.

According to the first embodiment, a first protective layer is formed of carbon using thermal CVD at a relatively high temperature after a magnetic recording layer is formed. Therefore, the surface coating of the first protective layer can be improved and sufficient surface smoothness can be obtained without providing a cooling step in particular between a step of forming the magnetic recording layer and a step of forming the first protective layer.

As the magnetic recording layer, a heat-assisted magnetic recording layer can be used. The heat-assisted magnetic recording layer is formed of a magnetic material having an L1₀ crystal structure. This magnetic material may include an FePt-based alloy, a CoPt-based alloy, an FePd-based alloy, and the like.

The heat sink layer may include a high thermal conductivity metal such as Ag, Au, Cu and Al, an alloy of these metals, and the like.

In addition, the crystal orientation layer may include MgO, Cr, Ta and the like.

Reactant gas can be used to form the first protective layer of carbon using thermal CVD. The reactant gas may include hydrocarbon gas such as ethylene gas (C₂H₄), alkane (CₙH₂ₙ₊₂), alkene (CₙH₂ₙ), and alkyne (CₙH₂ₙ₋₂).

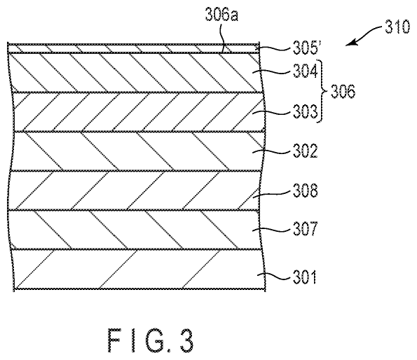

FIG. 3 is a sectional view showing another example of the magnetic recording medium according to the first embodiment.

FIG. 3 shows a magnetic recording medium 310. The magnetic recording medium 310 has the same configuration as that of the magnetic recording medium 300 shown in FIG. 1, except that a second protective layer 304 of carbon is formed further on the first protective layer 303 by a method other than thermal CVD method.

The surface coating of the second protective layer 304 can improve wear resistance and corrosion resistance and thus improve the reliability of the magnetic recording medium.

The second protective layer of carbon can be formed by sputtering, plasma CVD, filtered cathodic arc, or the like.

Furthermore, for example, a fluorine-based lubricant is applied onto the outermost surface 303a of the first protective layer 303 shown in FIG. 1 and onto the outermost surface 306a of the third protective layer 306 shown in FIG. 3 to form a liquid lubricant layer 305′ thereon.

In order to improve the adhesion of liquid lubricant, the foregoing outermost surfaces 303a and 306a can be subjected to surface treatment such as nitrogen plasma treatment.

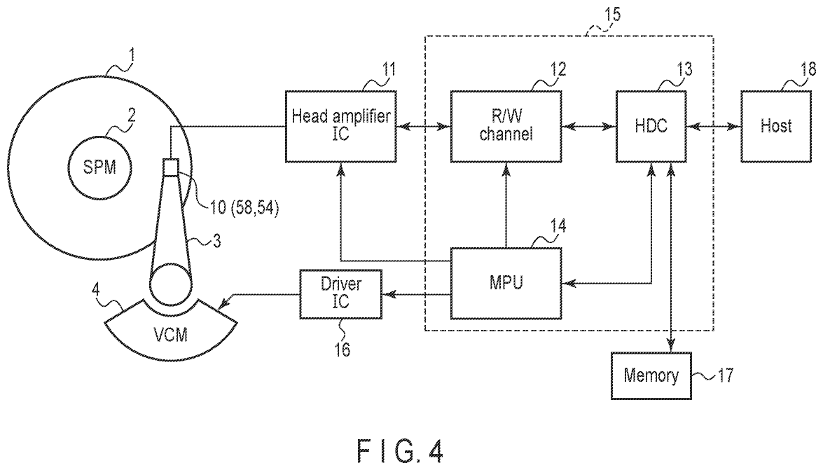

The configuration of a disk drive will be described below with reference to FIG. 4, as an example of a magnetic recording/reproducing apparatus according to a third embodiment.

As shown in FIG. 4, the disk drive is a magnetic disk drive for perpendicular magnetic recording, which incorporates a magnetic disk 1 (referred to simply as a disk hereinafter) serving as a perpendicular magnetic recording medium and a magnetic head 10 having a magnetic flux control layer (described later).

The disk 1 is fixed to a spindle motor (SPM) 2 to be rotated. The magnetic head 10 is mounted on an actuator 3 and is configured to move on the disk 1 in its radial direction. The actuator 3 is rotated by a voice coil motor (VCM) 4. The magnetic head 10 includes a recording (write) head 58 and a reproducing (read) head 54.

The disk 1 also includes a head amplifier integrated circuit (hereinafter referred to as a head amplifier IC) 11, a read/write channel (R/W channel) 12, a hard disk controller (HDC) 13, a microprocessor (MPU) 14, a driver IC 16 and a memory 17. The R/W channel 12, HDC 13 and MPU 14 are incorporated into a controller 15 composed of a one-chip integrated circuit.

The head amplifier IC 11 includes a circuit group that controls laser light, as will be described later.

The head amplifier IC 11 further includes a driver that supplies a recording head 58 with a recording signal (write current) corresponding to write data supplied from the R/W channel 12. The head amplifier IC 11 also includes a read amplifier that amplifies a read signal output from a reproducing head 54 and transmits the amplified read signal to the R/W channel 12.

The R/W channel 12 is a signal processing circuit for read/write data. The HDC 13 constitutes an interface between the disk drive and a host 18, and performs transfer control of the read/write data.

The MPU 14 is a main controller of the disk drive to control read/write operation and perform servo control necessary for positioning the magnetic head 10. The memory 17 includes a flash memory and a buffer memory including a DRAM, and the like.

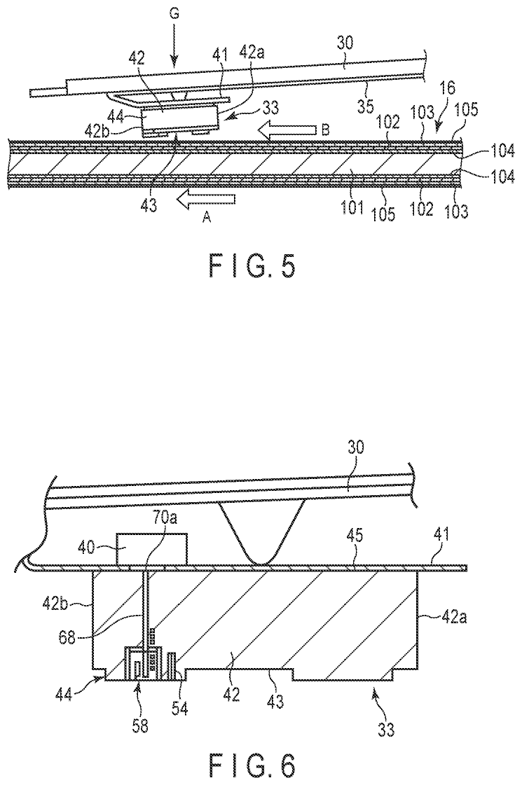

FIG. 5 is a side view showing the magnetic head and a suspension.

As shown in FIG. 5, the magnetic head 33 as the magnetic head 10 is configured as a floating head, and includes a slider 42 shaped like a substantially rectangular parallelepiped, and a recording/reproducing head portion 44 provided at an outflow end (trailing edge) of the slider 42. The magnetic head 33 is fixed to a gimbal spring 41 provided at the tip of the suspension 30. A head load G is applied to the magnetic head 33 toward the surface of the magnetic disk 16 as the magnetic disk 1, by elasticity of the suspension 30. As shown in FIG. 5, the magnetic head 33 is connected to the head amplifier IC 11 and the HDC 13 via a wiring member (flexure) 35 fixed on the suspension 30 and arm.

The configuration of the magnetic disk 16 and the magnetic head 33 will be described in detail below.

As shown in FIG. 5, the magnetic disk 16 includes a substrate 101 that is formed of a disk-shaped nonmagnetic substance whose diameter is, for example, about 3.5 inches (9.5 cm or 9.6 cm). On the surface of the substrate 101, a heat sink layer 104 for suppressing the expansion of a heating region, a crystal orientation layer 102 for improving the orientation of a magnetic recording layer, a magnetic recording layer 103, a first protective layer 105 formed of carbon by thermal CVD, and a liquid lubricant (not shown) are stacked in order. The protective layer 105 is a carbon film formed by thermal CVD. As the magnetic disk 16, a magnetic disk having a substrate the size of which is, for example, 2.5 inches (6.35 cm) can be used.

The body of the slider 42, which is provided with the magnetic head 33, is formed of, for example, a sintered body (AlTiC) of alumina and titanium carbide, and the head portion 44 is formed by laminating thin films. The slider 42 has a rectangular disk-opposed surface (air bearing surface (ABS)) 43 which is opposed to the surface of the magnetic disk 16. The slider 42 is floated by air flow B generated between the disk surface and the ABS 43 by the rotation of the magnetic disk 16. The direction of air flow B coincides with the rotational direction A of the magnetic disk 16. The slider 42 is disposed with respect to the surface of the magnetic disk 16 such that the longitudinal direction of the ABS 43 substantially coincides with the direction of air flow B.

The slider 42 has a leading edge 42a located on the inflow side of air flow B and a trailing edge 42b located on the outflow side of air flow B. In the ABS 43 of the slider 42, a leading step, a trailing step, a side step, a vacuum cavity and the like (none of which is shown) are formed.

As shown in FIGS. 5 to 7, a magnetic head 33 is configured as a floating head to include the slider 42 shaped like a substantially rectangular parallelepiped and the head portion 44 provided at the outflow end (trailing edge) of the slider 42. The slider 42 is formed of, for example, a sintered body (AlTiC) of alumina and titanium carbide, and the head portion 44 is formed by laminating thin films.

The slider 42 has a rectangular floating surface (air bearing surface (ABS)) 43 opposed to the disk surface, and a rectangular slider bearing surface 45 on the opposite side of the floating surface. The slider bearing surface 45 of the slider 42 is attached to the gimbal spring 41. In addition, on the slider bearing surface 45 or the gimbal spring 41, a laser generating element (laser diode) 40 is mounted as a light source.

The slider 42 is floated by air flow B that is generated between the disk surface and the floating surface 43 by the rotation of the magnetic disk 16. The direction of air flow B coincides with the rotation direction A of the magnetic disk 16. The slider 42 is so disposed that the longitudinal direction of the floating surface 43 almost coincides with the direction of air flow B with respect to the disk surface.

The slider 42 has a leading edge 42a located on the inflow side of air flow B and a trailing edge 42b located on the outflow side of air flow B. On the floating surface 43 of the slider 42, an uneven structure (a leading step, a trailing step, a side step, a vacuum cavity, etc.), which is not shown, is formed.

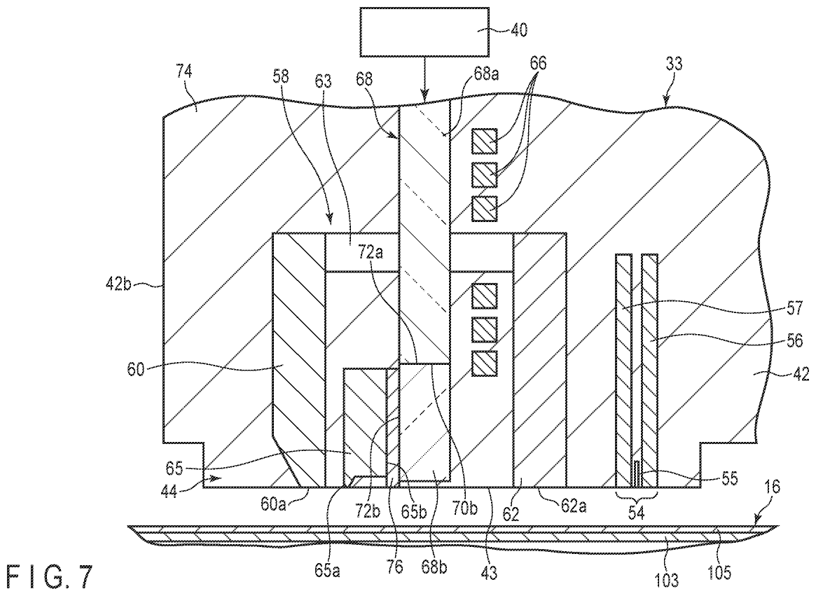

As shown in FIGS. 6 and 7, the head portion 44 includes the reproducing head 54 and recording head (magnetic recording head) 58, which are formed by a thin film process, at the trailing edge 42b of the slider 42, and is formed as a detachable magnetic head.

The reproducing head 54 is configured by a magnetic film 55 that produces a magnetoresistance effect, and shield films 56 and 57 arranged on the trailing and leading sides of the magnetic film 55 so as to sandwich the magnetic film 55. The lower ends of the magnetic film 55 and shield films 56 and 57 are exposed to the floating surface 43 of the slider 42.

The recording head 58 is provided closer to the trailing edge 42b of the slider 42 with respect to the reproducing head 54. The recording head 58 includes a main magnetic pole 60 which is made of soft magnetic materials having high magnetic permeability and high saturation magnetic flux density to generate a recording magnetic field in a direction perpendicular to the disk surface (to the recording layer 103), a leading yoke 62 which is placed on the leading side of the main magnetic pole 60 and is made of soft magnetic materials that cause a magnetic flux to flow through the main magnetic pole 60, a bonding portion 63 which physically bonds an upper part of the leading yoke 62 (an end portion spaced from the floating surface 43) to the main magnetic pole 60, a recording coil 66 which is provided so as to be wound around a magnetic path including the leading yoke 62 and the main magnetic pole 60 to cause a magnetic flux to flow through the main magnetic pole 60, a near-field light generating element (a plasmon generator, a near-field transducer) 65 which is placed on the leading side of the main magnetic pole 60 to generates near-field light for heating the recording layer 103 of the magnetic disk 16, and a waveguide 68 to guide light to the near-field light generating element 65. The near-field light generating element 65 is a light generating element that generates light directed to the magnetic disk 16. The waveguide 68 propagates the light for near-field light generation to the near-field light generating element 65. The tip surface 60a of the main magnetic pole 60, the tip surface 62a of the leading yoke 62, and the tip (plasmon antenna) 65a of the near-field light generating element 65 are exposed to the floating surface 43 of the slider 42.

The waveguide 68 includes a first waveguide 68a extending from the slider bearing surface 45 of the slider 42 to the vicinity of the near-field light generating element 65 toward the floating surface 43, and a second waveguide 68b extending from the lower end of the first waveguide 68a to the vicinity of the floating surface 43. The first and second waveguides 68a and 68b extend along a direction substantially perpendicular to the floating surface 43.

The first waveguide 68a has a first incidence surface 70a located on the slider bearing surface 45 of the slider 42 and a first emission surface 70b at the lower end of the first waveguide 68a. The first emission surface 70b is formed almost in parallel with the floating surface 43 and is opposed to the laser generating element 40. The second waveguide 68b has a second incidence surface 72a located at the upper end thereof and in parallel to the slider bearing surface 45a, and a second emission surface 72b extending perpendicularly to the second incidence surface 72a. The second incidence surface 72a of the second waveguide 68b abuts on, i.e. is bonded to the first emission surface 70b of the first waveguide 68a. Thus, the first and second waveguides 68a and 68b extend continuously and linearly. The second emission surface 72b of the second waveguide 68b extends substantially perpendicular to the floating surface 43 and faces the near-field light generating element 65.

The near-field light generating element 65 has a tip (plasmon antenna) 65a projecting from its lower end and exposed to the floating surface 43, a third incidence surface 65b opposed to the second waveguide 68b, and another side opposed to the third incidence surface 65b. The third incidence surface 65b extends substantially perpendicularly to the floating surface from the vicinity of the floating surface 43. The third incidence surface 65b is also opposed to the second emission surface 72b of the second waveguide 68b in parallel with a slight gap therebetween. Between the third incidence surface 65b of the near-field light generating element 65 and the second emission surface 72b of the second waveguide 68b, a low refractive index layer 76 is provided. The low refractive index layer 76 is formed of a material, for example, silicon oxide, the refractive index of which is lower than that of the second waveguide 68b. Note that the periphery of the second waveguide 68b may be covered with a silicon oxide layer.

The current supplied to the recording coil 66 of the recording head 58 and the drive current of the laser generating element 40 are controlled by a control circuit board (controller) of the HDD. When a signal is written to the recording layer 103 of the magnetic disk 16, a predetermined current is supplied from a power source to the recording coil 66 to cause a magnetic flux to flow through the main magnetic pole 60 and thus generate a magnetic field. In addition, laser light (excitation light) generated from the laser generating element 40 as a light source is input to the waveguide 68, and supplied to the near-field light generating element 65 through the waveguide 68.

According to the HDD configured as described above, the VCM 4 is driven to rotate an actuator 3, and the magnetic head 33 is moved onto a desired track of the magnetic disk 16 and positioned thereon. The magnetic head 33 is also floated by air flow B generated between the disk surface and the floating surface 43 by the rotation of the magnetic disk 16. In operating the HDD, the floating surface 43 of the slider 42 is opposed to the disk surface with a gap therebetween. In this state, recording information is read from the magnetic disk 16 by the reproducing head 54, and information (signal) is written thereto by the recording head 58.

In writing formation, the information is recorded with a desired track width by exciting the main magnetic pole 60 by the recording coil 66 and applying a perpendicular-direction recording magnetic field from the main magnetic pole 60 to the recording layer 103 of the magnetic disk 16 located directly under the main magnetic pole 60. In addition, the laser generating element 40 supplies laser light to the near-field light generating element 65 through the waveguide 68, and the near-field light generating element 65 generates near-field light. The recording layer 103 of the magnetic disk 16 is locally heated by the near-field light generated from the tip 65a of the near-field light generating element 65 to lower the coercivity of a portion of the recording layer 103. A recording magnetic field is applied from the main magnetic pole 60 to the portion whose coercive force is lowered to write a signal thereto. If, therefore, a signal is written to a portion of the recording layer 103 whose coercive force is sufficiently lowered by locally heating the portion of the recording layer 103, high-density magnetic recording can be achieved. The tip 65a of the near-field light generating element 65 and the tip portion 60a of the main magnetic pole 60 are provided close to each other in order to cool the magnetic disk 16 heated by the laser light and apply a head magnetic field to the magnetic disk 16 before the coercive force is restored.

When near-field light is applied from the near-field light generating element 65 to the magnetic disk 16, the laser light that enters the first waveguide 68a from the laser generating element 40 propagates through the first waveguide 68a while being repeatedly reflected by the core inner wall surface (side or perimeter) of the first waveguide 68a, and enters the second waveguide 68b through the first emission surface 70b and the second incidence surface 72a. The laser light further propagates through the second waveguide 68b while being repeatedly reflected by the core inner wall surface of the second waveguide 68b. When the laser light is reflected by the second emission surface 72b of the second waveguide 68b, surface plasmon is generated on the outside of the second emission surface 72b (outside of the second waveguide 68b). This surface plasmon is excited to the near-field light generating element 65 from the third incidence surface 65b thereof, and the near-field light generating element 65 irradiates the recording layer 103 of the magnetic disk 16 with near-field light from the tip (plasmon antenna) 65a.

The embodiments will be described more specifically by the following examples.

### Example 1

A manufacturing process of Example 1 will be described with reference to the flowchart shown in FIG. 2.

First, a 3.5-inch glass substrate is prepared as a substrate.

The glass substrate is placed on the base of a sputtering apparatus, and a CuZr layer is formed to a thickness of 50 nm on the glass substrate by sputtering to form a heat sink layer (ST1).

Then, a crystal orientation layer including two layers of a Ta layer and an MgO layer is formed to a thickness of 20 nm on the heat sink layer (ST2).

Then, the base is heated to 500° C., and an FePt-based magnetic recording layer for the heat-assisted recording system, which has an L1₀ crystal structure, is formed by sputtering to a thickness of 10 nm (ST3).

Subsequently, in order to improve the magnetic characteristics of the resultant FePt-based magnetic recording layer, the temperature of the substrate is maintained at 500° C., and an ethylene gas (C₂H₄) is used as a source gas to form a first protective layer of carbon to a thickness of 2.0 nm by thermal CVD (ST4).

The resultant first protective layer is coated with a fluorine-based liquid lubricant to form a lubricating layer, thereby obtaining a magnetic recording medium.

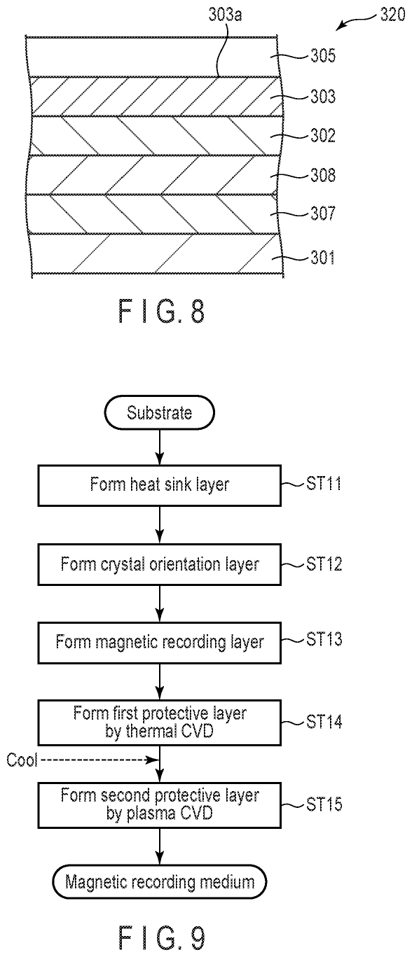

FIG. 8 is a sectional view showing a configuration of a magnetic recording medium of Example 1.

As shown in FIG. 8, a magnetic recording medium 320 for the heat-assisted recording system includes a glass substrate 301, a heat sink layer 307 of CuZr formed on the glass substrate 301, a crystal orientation layer 308 including two layers of a Ta layer and an MgO layer and formed on the heat sink layer 307, an FePt-based magnetic recording layer 302 formed on the crystal orientation layer 308, a first protective layer 303 of carbon formed on the FePt-based magnetic recording layer 302 by thermal CVD, and a fluorine-based lubricant layer 305 formed on the first protective layer 303.

With respect to the resultant magnetic recording medium 320, the arithmetic average roughness (Ra) of the outermost surface 303a was measured using NX-HDM of Park Systems Corp. and found to be 0.23 nm. The result obtained is shown in Table 2 below.

As is seen from Example 1, even though the first protective layer is formed continuously (ST4) with the substrate temperature at a high temperature of 500° C. after the magnetic recording layer is formed (ST3) by thermal CVD, the surface coating of the first protective layer is improved, and so is the smoothness of the outermost surface 303a of the first protective layer 303.

### Example 2

FIG. 9 is a flowchart showing a manufacturing method of Example 2.

A 3.5-inch glass substrate is prepared as a substrate.

The glass substrate is placed on the base of a sputtering apparatus, and a CuZr film is formed to a thickness of 50 nm on the glass substrate by sputtering to form a heat sink layer (ST11).

Then, a crystal orientation layer including two layers of a Ta layer and an MgO layer is formed to a thickness of 20 nm on the heat sink layer (ST12).

Then, the base is heated to 500° C. under vacuum, and an FePt magnetic recording layer having an L1₀ crystal structure is formed by sputtering to a thickness of 10 nm (ST13).

Subsequently, in order to improve the magnetic characteristics of the resultant FePt-based magnetic recording layer, the temperature of the substrate is maintained at 500° C., and an ethylene gas (C₂H₄) is used as a source gas to form a first protective layer of carbon to a thickness of 0.5 nm by thermal CVD (ST14).

After that, the substrate is optionally cooled to a temperature of approximately 200° C.

Then, an ethylene gas (C₂H₄) is used as a source gas to form a second protective layer of carbon to a thickness of 1.5 nm on the resultant first protective layer by plasma CVD (ST15).

In addition, the second protective layer is coated with a fluorine-based liquid lubricant to form a liquid lubricant layer, thereby obtaining a magnetic recording medium for the heat-assisted recording system.

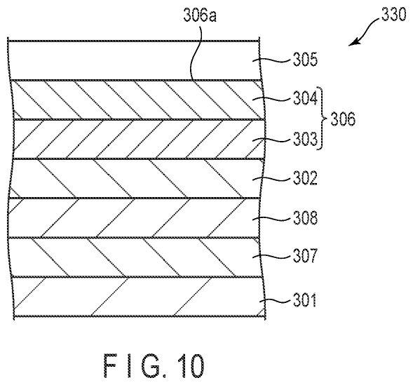

FIG. 10 is a sectional view showing a configuration of the magnetic recording medium of Example 2.

As shown in FIG. 10, a magnetic recording medium 330 for the heat-assisted recording system includes a glass substrate 301, a heat sink layer 307 of CuZr formed on the glass substrate 301, a crystal orientation layer 308 including two layers of a Ta layer and an MgO layer and formed on the heat sink layer 307, an FePt-based magnetic recording layer 302 formed on the crystal orientation layer 308, a first protective layer 303 of carbon formed on the FePt-based magnetic recording layer 302 by thermal CVD, a second protective layer 304 of carbon formed on the first protective layer 303 by plasma CVD, a protective layer 306 including the first and second protective layers 303 and 304 and formed on the FePt-based magnetic recording layer 302, and a fluorine-based lubricant layer 305 formed on the outermost surface 306a of the protective layer 306.

As in Example 1, the arithmetic average roughness (Ra) of the outermost surface 306a of the protective layer 306 was measured and found to be 0.24 nm. The result obtained is shown in Table 2 below.

In Example 2, even though the first protective layer is formed continuously (ST4) with the substrate temperature at a high temperature of 500° C. after the magnetic recording layer is formed (ST3) by thermal CVD, the surface coating of the first protective layer is improved. Since, furthermore, the second protective layer 304 formed of carbon by plasma CVD is stacked on the first protective layer 303 formed of carbon by thermal CVD, the abrasion resistance and corrosion resistance of the magnetic recording medium can be improved more than the magnetic recording medium obtained by forming only the first protective layer 303, and so can be the reliability of the magnetic recording medium.

### Comparative Example 1

As in Example 1, a heat sink layer, a crystal orientation layer and an FePt-based magnetic recording layer having an L1₀ crystal structure were formed on a 3.5-inch glass substrate. Then, as in Example 2, a first protective layer was formed of carbon to a thickness of 2.0 nm by plasma CVD to obtain a magnetic recording medium. As in Example 1, the arithmetic average roughness (Ra) was measured and found to be 0.35 nm.

In the comparative example, when a carbon protective layer was formed by plasma CVD continuously after the FePt-based magnetic recording layer was formed at 500° C., the substrate was not sufficiently cooled to a temperature of 200° C. which is suitable for plasma CVD. Thus, the surface coating became worse and the surface roughness became greater than that in Examples 1 and 2.

TABLE 2

| | | Arithmetic |
|---|---|---|
| | | average |
| | Protective layer | coating (Ra) |
| Example 1 | First carbon | 0.23 nm |
| | protective layer | |
| Example 2 | First and second | |
| | carbon protective | 0.24 nm |
| | layers | |
| Comparative | Second carbon | 0.35 nm |
| Example 1 | protective layer | |

As shown in Table 2, if thermal CVD is used to form a carbon protective layer on a magnetic recording layer as in Examples 1 and 2, the surface coating of the carbon protective layer is excellent and the surface roughness of the outermost surface thereof is lower, as compared with the case where plasma CVD is used.

If, furthermore, a first protective layer is formed on the magnetic recording layer by thermal CVD and a second protective layer is formed thereon by plasma CVD as in Example 2, its abrasion resistance and corrosion resistance can be improved, and so can be the reliability of the magnetic recording medium.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic recording medium comprising:
a substrate;
a magnetic recording layer on the substrate; and
a first protective layer of carbon formed on the magnetic recording layer by thermal CVD.

2. The magnetic recording medium of claim 1, wherein the magnetic recording layer includes an alloy having an L1₀ crystal structure.

3. The magnetic recording medium of claim 2, wherein the alloy having an L1₀ crystal structure is one of an FePt-based alloy, an FePd-based alloy, and a CoPt-based alloy.

4. The magnetic recording medium of claim 1, further comprising a second protective layer of carbon formed on the first protective layer by a film forming method other than the thermal CVD.

5. A magnetic recording/reproducing apparatus comprising:
a magnetic recording medium including a substrate, a magnetic recording layer formed on the substrate, and a first protective layer of carbon formed on the magnetic recording layer by thermal CVD; and
a magnetic head.

6. The magnetic recording/reproducing apparatus of claim 5, wherein the magnetic recording layer includes an alloy having an L1₀ crystal structure.

7. The magnetic recording/reproducing apparatus of claim 6, wherein the alloy having an L1₀ crystal structure is one of an FePt-based alloy, an FePd-based alloy, and a CoPt-based alloy.

8. The magnetic recording/reproducing apparatus of claim 5, further comprising a second protective layer of carbon formed on the first protective layer by a film forming method other than the thermal CVD.

9. A method of manufacturing a magnetic recording medium comprising:
forming a magnetic recording layer on a substrate; and
forming a first protective layer of carbon on the magnetic recording layer by thermal CVD.

10. The method of claim 9, wherein the magnetic recording layer includes an alloy having an L1₀ crystal structure.

11. The method of claim 10, wherein the alloy having an L1₀ crystal structure is one of an FePt-based alloy, an FePd-based alloy, and a CoPt-based alloy.

12. The method of claim 9, further comprising forming a second protective layer of carbon on the first protective layer by a film forming method other than the thermal CVD.
